(19) United States
(12) Patent Application Publication
(10) Pub. No.: US 2008/0186474 A1
(43) Pub. Date: Aug. 7, 2008

(54) Method and Apparatus for Measurement of Chromatic Aberrations of Optical Systems

(76) Inventors: Jacques Aschkenasy, Jerusalem (IL); Yakov Lyubchik, Kiryat Ekron (IL)

Correspondence Address: DEKEL PATENT LTD., DAVID KLEIN, BEIT HAROF'IM, 18 MENUHA VENAHALA STREET, ROOM 27, REHOVOT, 76209, omitted

(21) Appl. No.: 11/909,619

(22) PCT Filed: Jan. 23, 2006
(86) PCT No.: PCT/IL2006/000093

§ 371 Date: Sep. 25, 2007

(51) Int. Cl. G01N 21/00

(52) U.S. Cl. 356/73

(57) ABSTRACT

Disclosed is a method of measuring an optical system artifact that includes introduction into an optical path of a measurement target (64) having at least one edge. Illuminating a section of the edge by a first illumination and illuminating another section of the edge by a second illumination. The difference of the edge images generated by the optical system (60) when illuminated by the first illumination and the second illumination measured in a predefined plane represents the optical artifact.

### FIELD OF THE INVENTION

The present invention relates to the field of measurement of aberrations of optical systems, and particularly to the measurement of chromatic aberrations of optical systems.

### BACKGROUND

Optical systems are widely used in science and technology. They are an indispensable part of vision and measurement systems, lithography and metrology systems, projection systems and others. Optical systems assist in capturing data, in generating enlarged or reduced images of objects that should be tested, measured or just viewed. They work with monochromatic (or single color, or single wavelength light), or with polychromatic light, which is a mix of a plurality of wavelengths or colors. The term “monochromatic” as used in the present disclosure includes illumination that may be characterized by a narrow band spectrum, or quasi-monochromatic illumination. The term “light” as used in the present disclosure includes electromagnetic radiation with wavelength of several nanometers to tens microns.

Generally, optical systems have aberrations. Aberrations are artifacts of the optical systems. The index of refraction of lens material varies with the wavelength of light, i.e., lens material, which may be glass, bends different colors or wavelengths by different amounts. This phenomenon is called dispersion and among others is a reason for the chromatic aberration.

Optical systems may have different types of chromatic aberrations. Longitudinal chromatic aberration (CA) that causes light of different wavelengths (colors) to be focused in different planes. Lateral color aberration (LCA), also known as transverse chromatic aberration (TCA) or “lateral color”, which is generally defined as the difference in the image magnification as function of the wavelength, although in some existing optical systems, lateral color aberration is present also on the optical axis. Angular color aberration (ACA), which is the angular deviation of rays of different wavelengths. Knowledge of the magnitude of these aberrations is especially important in measurements that require sub-micron accuracy.

Known prior art includes U.S. Pat. No. 5,204,535 to Mizutani.

### BRIEF DESCRIPTION OF THE DRAWINGS

FIG. 1 is a schematic illustration of an optical set-up for measurement of the lateral color aberration;

FIGS. 2A and 2B are respectively schematic illustrations of the measurement target and the image of the target generated by the optical set-up of FIG. 1;

FIG. 3 is a schematic illustration of an optical set-up for measurement of the lateral color aberration at a number of wavelengths;

FIGS. 4A, 4B and 4C are schematic illustrations of the image plane of an additional embodiment of the optical set-up for measurement of the lateral color aberration;

FIG. 5 is a schematic illustration of the principles of measurement of the edges of a stripe of the measurement target;

FIGS. 6A, 6B and 6C are exemplary embodiments of the measurement targets;

FIG. 7 shows an example of measurement of lateral color aberrations for different spectral bands as compared with a reference wavelength band;

FIG. 8 is a schematic illustration of an additional embodiment of an optical set-up for measurement of the lateral color aberration;

FIG. 9 is a schematic illustration of a farther embodiment of an optical set-up for measurement of the lateral color aberration;

FIGS. 10A and 10B are schematic illustrations of additional exemplary embodiments of illumination systems for measurement of the lateral color aberration;

FIG. 11 is a schematic illustration of an embodiment of an optical set-up utilizing reflective optical elements for measurement of the lateral color aberration;

FIG. 12 is a schematic illustration of an additional embodiment of a set up for measurement of the lateral color aberration; and

FIG. 13A is a schematic illustration of a special filter used to measure lateral color aberration. FIG. 13B shows a schematic illustration of an image of an edge that is illuminated by optical system using the filter shown in FIG. 13A.

### DETAILED DESCRIPTION

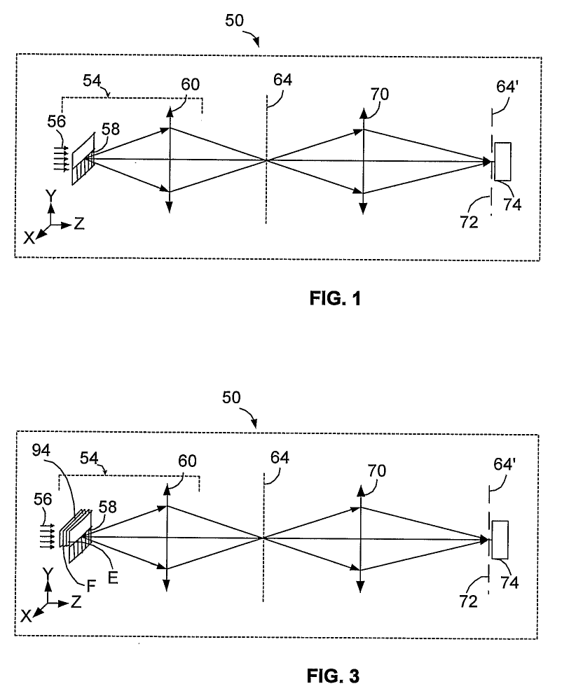

FIG. 1 is a schematic illustration of an optical set-up suitable for the measurement of the lateral color aberration. Optical set-up 50 typically includes an optical path along which are arranged an illumination system 54, a target 64, an optical system to be tested 70 and an image plane 72. Illumination system 54 further includes a source of illumination 56, which may be a polychromatic source such as an incandescent or flash lamp; the source of illumination 56 operates in continuous or flash mode. A color filter 58 positioned near or in the field conjugate of the optical system 60 covers part of the field of the illumination system and transforms at least a part of the polychromatic illumination into illumination with narrower spectral bands or monochromatic illumination. In the part of the field conjugate not covered by filter 58 another filter may be positioned. Although filter 58 is shown covering the field in the direction parallel to the X-axis it may be oriented in any direction.

The illumination system 54 directs illumination to target 64, which is typically a chrome-on-glass target bearing certain pattern. At least a section of the pattern should be “color neutral”, i.e., the ratio of transmission of the different features within the “color neutral” section should not depend on the spectral composition of the illumination. Similarly, for a reflective target, as needed for instance in optical setup as illustrated in FIG. 8, the ratio of reflectivity for different features of the “color neutral” section should not depend on the spectral composition of the illumination. Optical system to be tested 70 is inserted in the optical path in such a way that target 64 would be positioned in the object plane of system 70 and the image 64′ of target 64 would be in image plane 72 of system 70. A detector 74 such as a CCD camera or another illumination spot position sensitive detector captures the content of image plane 72.

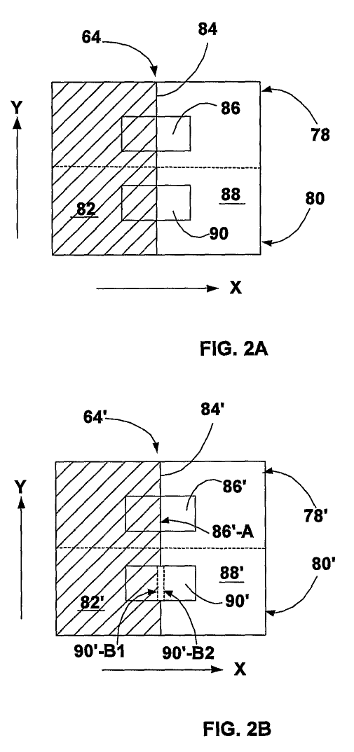

FIG. 2A is a schematic illustration of target 64 for measuring LCA in one direction at a certain region in the field of view, which in its simplest form may be a chrome-on-glass target having an opaque 82 section with at least one edge 84 and a transparent section 88. As used in the present disclosure the term “edge” means any object feature that could be imaged and according to which the image position may be defined. “Edge” could be a phase object also. In order to measure one of the chromatic aberrations and in particular the lateral chromatic aberration (LCA) of optical system 70, part 78 of target 64, shown as the upper part, is illuminated by the reference or “first” illumination. The other part 80, shown as lower part of target 64 is illuminated by the “second” illumination. This method of illumination causes a section of edge 84 located in part 78 of target 64 to be “colored” by light from the “first” illumination. This part can be used as reference for the measurement. The other section of edge 84 located in part 80 of target 64 is illuminated (“colored”) by the “second” illumination. Actually, it is not necessary to flood illuminate the whole target. It is enough to illuminate edge 84 by spots of first illumination 86 and second illumination 90. It should be emphasized here, that the edge sections illuminated by the first and second illumination do not have to belong to the same edge. Only for reasons of simplicity of the description only one edge (84) is shown here. The separating of the target illumination into “first” and “second” illumination can be achieved for instance by separating the field conjugate in the illumination system into two or more parts. An example for this can be seen in FIGS. 1 and 3.

FIG. 2B is a schematic illustration of image 64′ of target 64. Optical system 70 to be tested generates image 64′. Image 86′ of the target illuminated by spot 86 of the first illumination includes image 86′-A of respective section of edge 84. Image 90′ of target 64 illuminated by spot 90 of second illumination includes image 90′-B of respective section of edge 84. Image section 90′-B of edge 84 illuminated by the second illumination may include optical artifacts and particularly lateral chromatic aberration.

If the system to be tested has LCA the position of image 90′-B of section of edge 84 may depend on the spectral composition of the second illumination. Image locations 90′-B1, 90′-B2 or any other, shown in phantom lines, represent the different positions of image 90′-B of edge 84, depending on the chosen wavelength band for the second illumination. Camera 74 captures the image of target and allows determination of the positions 86′-A and 90′-B of the different sections of edge 84 illuminated by “first” and “second” illuminations. The position of the edges (or other features) can be done using common algorithms of image processing. In order to measure the LCA, at least two images should be taken, each with a different wavelengths band for the second illumination. The method defines LCA with respect to the image produced by the first or reference illumination. The spectral composition of the first illumination, illuminating the reference area 86 of the target 64, must remain constant for all the images. If the value of LCA has to be measured for a number of selected wavelengths, it could be measured for these particular wavelengths by illuminating section of edge 84 located in part 80 with respective wavelengths. Illumination with these selected wavelengths may be produced by transmitting the “white” illumination through a set of exchangeable filters 94 as shown in FIG. 3. For example, LAC for illumination produced by filters E and F may be found according to the following formula:

LCA_{E-F} (at the position defined by edge 84 and by the area 90)=[Edge position (second illumination, filter E, image 1)−Reference edge position (first illumination, image 1)]−[Edge position (second illumination, filter F, image 2)−Reference edge position first illumination, image 2)]

Use of the image of a section of edge 84 as reference for the measurement helps to reduce measurement errors that may be caused by undesired changes, such as target shift in the time between two successive images of different “colors” e.g. because of vibrations, thermal expansion, etc. The fact that the LCA is measured by comparing the edge position of different “colors” to the position of the edge of the reference area, which is illuminated by a light with constant “color”, is the reason for this.

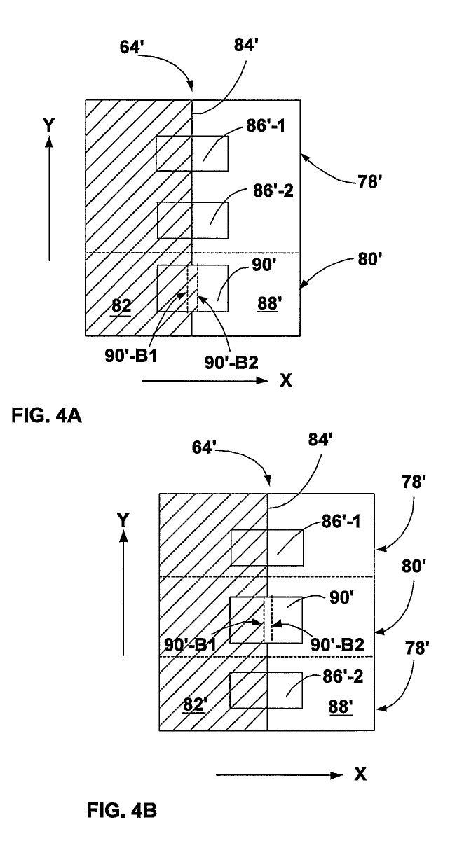

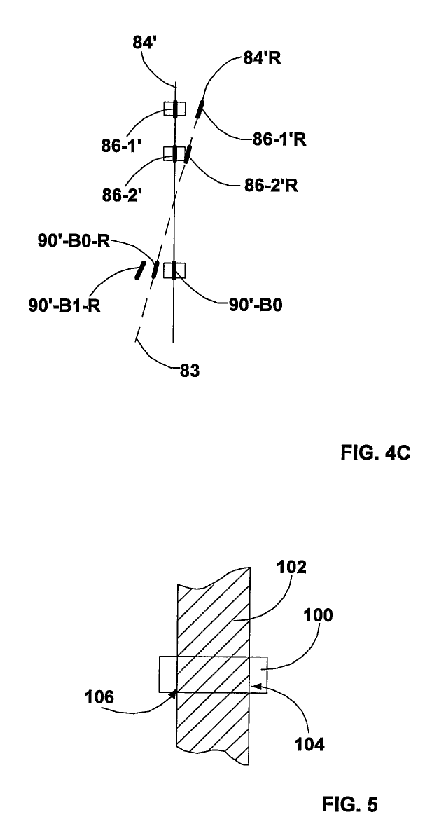

FIGS. 4A and 4B are schematic illustrations of image plane of an additional embodiment of the optical set-up and method for measurement of chromatic aberrations and in particular the lateral color aberration. The first or reference illumination may illuminate two or more sections of edge 84 of target 64 and accordingly to produce two or more reference images 86′-1 and 86′-2 of edge 84. Should target 64 move or rotate during the measurements, as shown in FIG. 4C, the images of sections 86′-1 and 86′-2 illuminated by reference illumination will shift. This target rotation can be measured and a correction of the measurement error of the LCA, caused by the target rotation, may be introduced. If no color aberration would be present, the image of the section of edge 84 illuminated by spot 90 would be on the rotated edge 84R′ (Suffix R marks the rotated images.) and it could be observed as image 90′-B0-R. Presence of the color aberration causes the image of the section of edge 84 illuminated by spot 90 to be located in position 90′-B1 -R. Thus by measuring the target rotation angle for each of the images it is possible to correct the measurement errors caused by target 64 rotation between successive image measurements. The ability to correct the results of the measurements for the errors caused by the target rotation makes the method immune to shifts and other movements of target position and/or of other components in the setup that may occur between successive measurements.

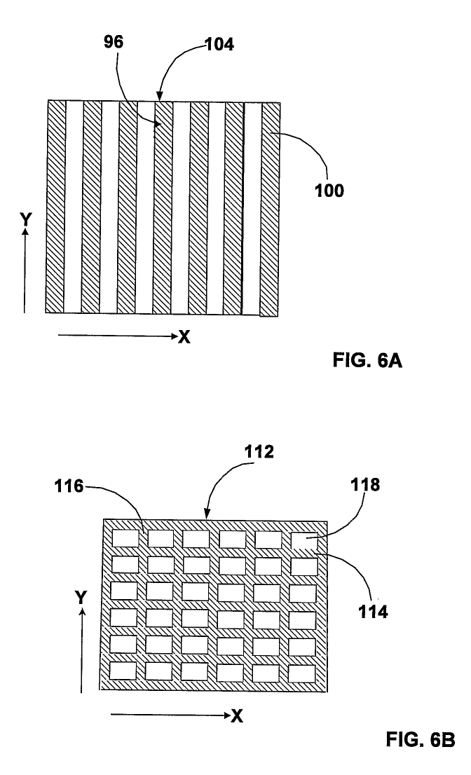

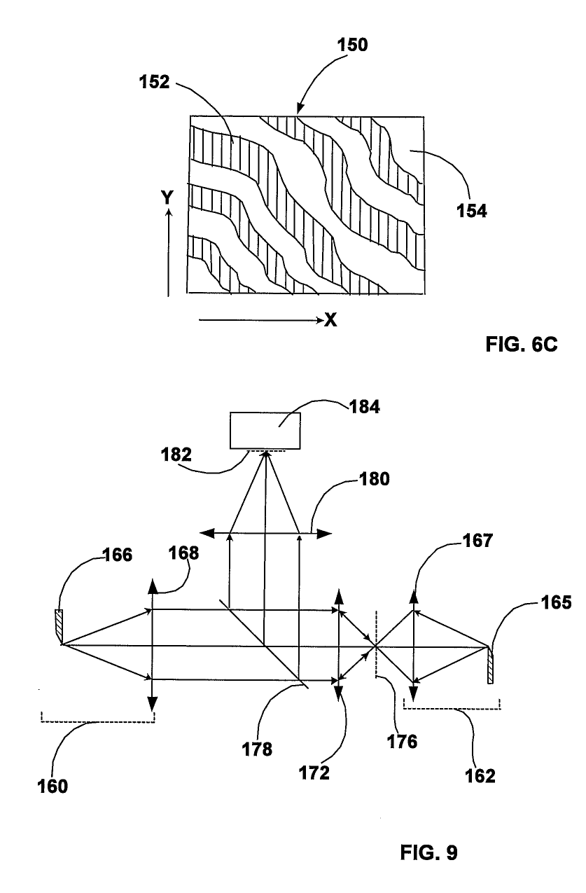

The accuracy of aberration measurement may be further increased if instead of measuring a single edge position, such as edge 84 of target 64, position of two edges of a strip would be measured and the result of the measurement would be averaged. Reference is now made to FIG. 5, which illustrates this method of measurement. Illumination spot 100 could be selected to exceed the width of stripe 102. Position of stripe 102 edges 104 and 106 may be measured and accordingly determination of the position of stripe 100 becomes more accurate than that of the position of a single edge. FIG. 6A shows an exemplary embodiment of a multiple stripe target 104. Such targets allow LCA measurement in one direction, e.g. X-direction and at different places in the field of view. FIG. 6B illustrates an additional embodiment of measurement targets 112. Performing measurements on orthogonal stripes 114 and 116 of target 112 of FIG. 6B enables LCA determination of the optical imaging system in both X and Y directions. FIG. 6C illustrates yet another embodiment of measurement target 150 having a pattern 152, 154. Alternatively, openings 118 may be made opaque with their edges providing two orthogonal measurement directions. Targets 104, 112 and 150 as measurement targets may replace target 64.

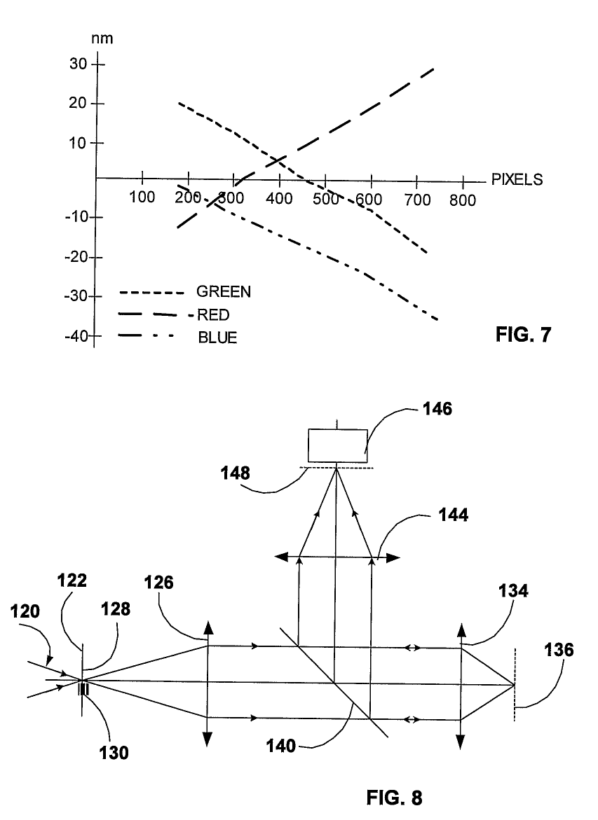

FIG. 7 shows an example of results of measurement of lateral color aberration for 3 colors within a field of view (in pixels of an imager) as compared to a reference spectral band.

FIG. 8 is a schematic illustration of an additional embodiment of a set up for measurement of the aberrations (lateral color aberration) of an optical system. Illumination 120 is provided by a source of illumination (not shown) that may have certain beam forming optics. The source of illumination may be a polychromatic source or an assembly of Light Emitting Diodes (LEDs), lasers, or other light sources; it may be positioned in the optical system or at a remote place and the light might be brought to the optical system using light guides, fiber optics or any appropriate mean. Plane 122 could be an infinite conjugate of illumination system 126 and an optical conjugate of the plane where measurement target 136 is located. If the source of illumination is a polychromatic source, a narrow band filter 128 may be used to provide the reference illumination. A set of exchangeable filters 130 may provide a number of monochromatic illuminations for performing the measurement. Each of filters 130 provides monochromatic (or narrow band) illumination of a different wavelength (or color, accordingly). Alternatively, a group of LEDs emitting at different wavelengths may be used. Filter 128 and the particular operable filter of set of filters 130 are located in plane 122. Illumination system 126 directs illumination 120 to optical system 134 to be tested. Optical system 134, eventually together with tube lens 144 forms monochromatic and polychromatic images of sections of target 136. Target 136 may be a reflective target similar in its structure to the earlier described targets. Optical system 134 collects the reflected by target 136 illumination and directs it with the help of beam splitter 140 and tube lens 144 or other auxiliary optics to a camera 146 where image 148 of target 136 is formed. The principles of measurement of image 148 have been explained earlier. Beam splitter 140 is typically a 50%-50% beam splitter, but it may have any other proportion between the transmitted and reflected light. A mirror, or a pellicle, or any other beam-splitting device supporting the required functionality may substitute beam splitter 140. The optical setup can be changed also, so that the beam splitter 140 transmits instead of reflecting the target image to the camera.

FIG. 9 is a schematic illustration of a further embodiment of an optical set-up for measurement of the lateral color aberration. This embodiment is characterized in that it uses two illumination systems 160 and 162, for example located on the opposite sides of the optical path. Each illumination system may include a source of illumination (not shown), a field stop 166 and 165, and illumination beam forming optics 168 and 167. Illumination systems 160 and 162 have their field stops 166 and 165 optically conjugate with the plane where measurement target 176 is located. One of the illuminations systems provides the first or reference illumination and the other one provides the second or the measurement illumination. Illumination systems 160 and 162 direct illumination to optical system 172 that is tested. Optical system 172 collects the illuminations reflected and transmitted by target 176 and directs it with the help of beam splitter 178 and tube lens 180 or other auxiliary optics to a camera 184 where image 182 of target 176 is formed. Target 176 may be similar in its structure to the above-described targets. The principles of measurement of image 182 have been explained above. Beam splitter 178 could be a 50%-50% beam splitter or may have any other proportion between the transmitted and reflected light. A mirror, or a pellicle, or any other beam-splitting device supporting the required functionality may substitute beam splitter 178. The optical setup can be changed also, so that the beamsplitter 178 transmits instead of reflects the target image to the camera.

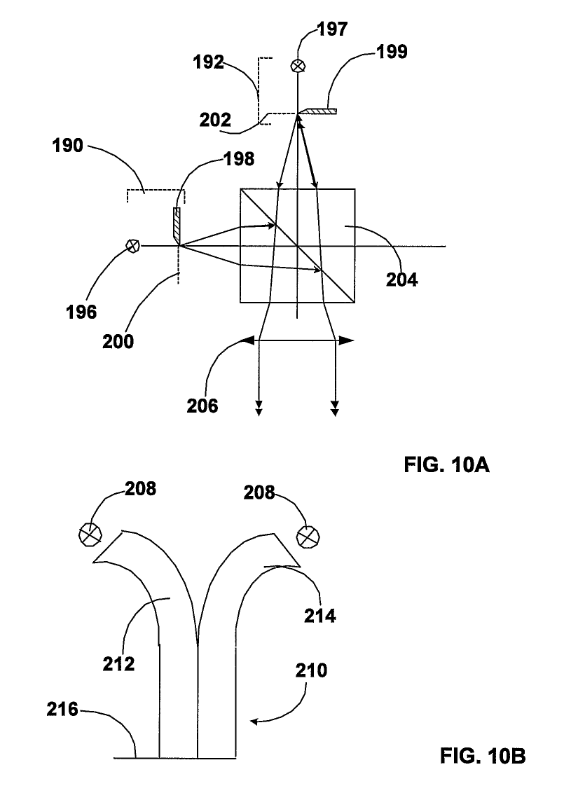

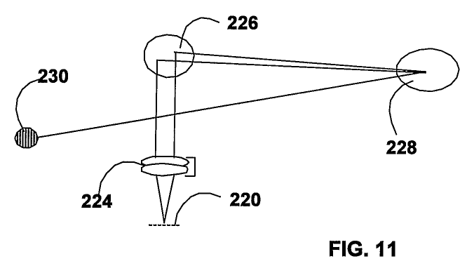

FIGS. 10A and 10B are schematic illustrations of additional exemplary embodiments of illumination systems for measurement of the lateral color aberration. FIG. 10A shows an illumination system that may use a beam combiner 204 to combine into one illumination beam the illumination that illumination systems 190 and 192 located on the respective sides of beam combiner 204 provide. Each illumination system may include a source of illumination 196 and 197, a field stop 198 and 199, illumination-forming optics (not shown) and a set of exchangeable color filters 200 and 202. Field stops 198 and 199 may cover complementary sections of the field view of the imaging systems. The color filters 200 and 202 may be positioned anywhere between the light sources 196 and 197 and the beam combiner 204. For instance, if the illumination is brought to the optical system through fiber optics, the color filters may be positioned at the distant end of the fiber optics. Each of systems 190 and 192 may provide the first or reference and the second or measurement illumination and their filters are selected accordingly. Polychromatic (“white”) illumination is usually provided by incandescent lamps, white LEDs or other illumination sources and does not require use of filter, unless certain predefined spectrum is needed. If illumination systems 190 and 192 instead of “white” light source use LEDs there might be no need in filters. FIG. 10B illustrates an alternative illumination system 210 that includes light sources 208 and proper spliced light guides 212 and 214, such as fiber optics guides. Plane 216 may be conjugate to the target plane in the optical system.

Tube lenses 144 (FIG. 8) and 180 (FIG. 9) may affect the results of the measurements. In order to reduce or eliminate the influence of color aberrations of tube lenses a reflective optical path, as illustrated in FIG. 11, may be used. In this embodiment, target 220 may be illuminated by any one of illumination sources described above. Optical system to be tested 224 collects the reflected or transmitted illumination and directs it to a reflective optical set-up that may further include an optional folding mirror 226 and a reflector 228. Folding mirror 226 and reflector 228 may have spherical, parabolic or any other type of aspherical surfaces that may be tilted. The reflective optical set-up forms image 230 of target 220 in a predefined plane where a camera (not shown) may be located. It is clear that in case of finite imaging system tube lens, reflector or any other additional optical element for providing the image on the camera is not needed.

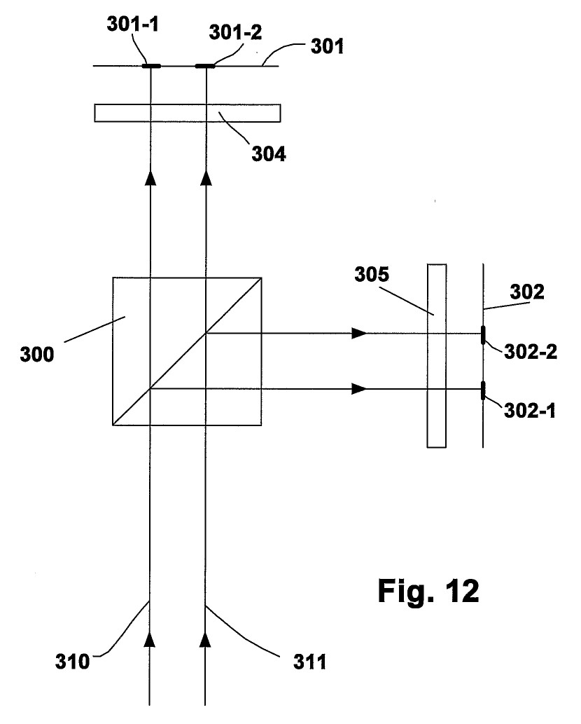

FIG. 12 is a schematic illustration of an additional embodiment of a set up for measurement of the lateral color aberration of optical systems. Here, instead of taking the two or more images at different times (temporally separated), the separation is done spatially. The light beams 310 and 311 are splitted by a beamsplitter 300 before falling on the imager and fall at the end onto two separated imagers 301 and 302 or on different parts of the same imager (optical scheme for this version not shown here). Beam 310 comes from first illumination and 311 from the second illumination. Filters 304 and 305 are designed so that they do not affect the “color” of the first illumination, but do affect the second illumination. Filter 304 transmits from the second illumination only a chosen wavelengths band (called here “E”) and filter 305 transmits only wavelengths band “F” of the second illumination. The LCA can be evaluated by comparing images from the two imagers 301 and 302 (or from images of different parts of the same imager; optical scheme for this version not shown here). 301-1 and 302-1 represent the areas, where edges and/or features from the first illumination are imaged, which can be used for the reference and 301-2 and 302-2 are the areas, where the aberrations are measured. As mentioned, the filters 304 and 305 do not affect the “color” of the first illumination. This can be done for instance by leaving the relevant part of the filters uncoated, by cutting the filters accordingly or by use of an appropriate coating on the filters. Instead of the filters 304 and 305, the beam splitter 300 could be designed so that color “E” is transmitted through it, whereas color “F” is reflected.

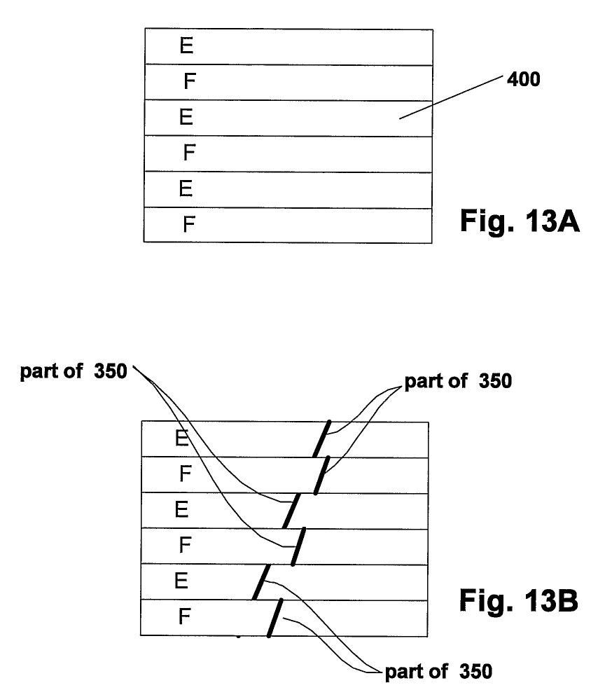

In another embodiment for measuring the lateral color aberration a special configuration of filter assembly is used as exemplified in FIG. 13A. The filter assembly is actually an array of filters with different spectral transmittance. In the example in FIG. 13A two kinds of sub-filters, named “E” and “F” are shown, but the filter may be built from more kinds of sub-filters and the array might be also two-dimensional. These filters can be used for example in an optical set up, as shown in FIG. 1. The filters, which may cover the whole field of view, may be positioned instead of filter 58 in FIG. 1. The image 350 of an edge illuminated in a set up using such kind of filter may look as shown in FIG. 13B and from this image it may be possible to calculate the lateral color aberration, assuming that edge used is straight enough and that the lateral color aberration does not change rapidly in the field of view. It will be understood that various configurations of filter assembly may be used.

Another possible placement for the filter is near to the image plane; the filter may even be attached to the imager. Actually many color imager make use of such kind of filters; often filters termed “Bayer filters” are used in these imagers. The same idea can be used also with a slightly different type of imager, as described for instance in the U.S. Pat. No. 6,727,521. In this case the color separation is done vertically instead of horizontally.

A number of embodiments have been described. Nevertheless, it will be understood that various modifications may be made without departing from the spirit and scope of the disclosure. Accordingly, other embodiments are within the scope of the following claims.

1. An imaging method for use in determining artifacts of an optical system, the method comprising: using said optical system for acquiring at least two images of a patterned target, wherein each said image having at least one reference area and at least one measurement area, all said reference image areas being generated identically for all said images and said measurement areas being generated at different wavelengths for each said image, thereby enabling determination of the artifact of the optical system by comparing positions of the pattern image in the measurement areas of said at least two images, wherein said positions of the pattern image in the measurement areas being determined relative to positions of the pattern image in the reference areas of the corresponding images.

2. The method of claim 1, wherein said optical artifact is at least one of a group of lateral color aberration, longitudinal chromatic aberration and angular color aberration.

3. The method of claim 1, wherein said measurement target having a pattern including sections with different transparency.

4. The method of claim 1, wherein said measurement target having a pattern including sections with different reflection.

5. The method of claim 1, wherein said acquiring at least two images includes illuminating the area of the target corresponding to the reference area of the image with reference wavelengths and illuminating the area of the target corresponding to the measurement area of the image with at least two different measurement wavelengths.

6. The method of claim 5, wherein said illuminating includes providing optical filters.

7. The method of claim 5, wherein said illuminations are operable in a continuous mode.

8. The method of claim 5 wherein said first and second illuminations are operable in flash mode.

9. The method of claim 1, wherein said acquiring at least two images is separated at time.

10. The method of claim 1, wherein said acquiring at least two images is spatially separated.

11. A system comprising:
i) a patterned target; ii) an optical system to be tested, and iii) an image acquisition assembly capable to acquire at least two images of said patterned target, wherein each said image having at least one reference area and at least one measurement area, all said reference image areas being generated identically for all said images and said measurement areas being generated at different wavelengths for each said image, thereby enabling determination of the artifact of the optical system by comparing positions of the pattern image in the measurement areas of said at least two images, wherein said positions of the pattern image in the measurement areas being determined relative to positions of the pattern image in the reference areas of the corresponding images.

12. A system of claim 11, wherein said image acquisition assembly includes an illumination system operable in continuous or in flash mode.

13. A system of claim 11, wherein said image acquisition assembly includes an illumination system providing an illumination of variable wavelength.

14. A system of claim 12, wherein said illumination system illuminates at least two different areas of said patterned target.

15. An apparatus of claim 12, wherein said illumination system illuminates at least one area of said patterned target with illumination of variable wavelength.

16. An apparatus of claim 11, wherein said optical artifact to be measured is one of a group of lateral color aberration, longitudinal chromatic aberration and angular color aberration.

17. An apparatus of claim 11, wherein said image acquisition assembly comprising at least two optical filters.

18. The target of claim 11, wherein said patterned target is chrome-on-glass target.

19. The illumination source of claim 11, wherein said illumination system includes at least one of a group of incandescent lamp, arc lamp, LEDs including UV LEDs, laser diodes, lasers and fiber optics waveguides.

20. An apparatus of claim 11, wherein said image acquisition assembly includes a detector being one of a group of charge coupled devices, charge induced devices and position sensitive detectors.

21-23. (canceled)
